(19) United States
(12) Patent Application Publication
(10) Pub. No.: US 2026/0293565 A1
(43) Pub. Date: Sep. 24, 2026

(54) METHOD FOR MANUFACTURING A PLURALITY OF SEMICONDUCTOR CHIPS

(71) Applicant: ams-OSRAM International GmbH, Regensburg (DE)

(72) Inventors: Michael Alexander Bergmann, Regensburg (DE); Hubert Halbritter, Dietfurt (DE)

(21) Appl. No.: 19/475,383

(22) PCT Filed: Mar. 21, 2024
(86) PCT No.: PCT/EP2024/057617

§ 371 Date: Oct. 14, 2025

(30) Foreign Application Priority Data
Apr. 19, 2023 (DE) 10 2023 109 861.6

(51) Int. Cl. H10P 58/00; H10P 50/61

(52) U.S. Cl. CPC H10P 58/20; H10P 50/613

(57) ABSTRACT

In an embodiment a method includes providing a functional semiconductor wafer having an epitaxial semiconductor layer sequence with a plurality of chip regions, wherein the epitaxial semiconductor layer sequence is arranged on a growth substrate and a sacrificial layer is arranged at least between the chip regions and the growth substrate, providing a carrier wafer, bonding the functional semiconductor wafer and the carrier wafer together such that a wafer compound is achieved, generating grooves between the chip regions through the growth substrate and the sacrificial layer such that the sacrificial layer is accessible through the grooves, arranging the wafer compound and a second ECE contact in an electrochemical etchant, and electrochemical etching the sacrificial layer by applying an ECE voltage between a first ECE contact and the second ECE contact.

### CROSS-REFERENCE TO RELATED APPLICATIONS

This patent application is a national phase filing under section 371 of PCT/EP 2024/057617, filed Mar. 21, 2024, which claims the priority of German patent application no. 102023109861.6, filed Apr. 19, 2023, each of which is incorporated herein by reference in its entirety.

### TECHNICAL FIELD

A method for manufacturing a plurality of semiconductor chips is provided.

### SUMMARY

Embodiments provide an improved method for manufacturing a plurality of semiconductor chips. Particularly, embodiments provide a simplified method for manufacturing a plurality of semiconductor chips, wherein a growth substrate is removed from a semiconductor layer sequence on wafer level in a simplified manner.

According to an embodiment of the method for manufacturing a plurality of semiconductor chips, a functional semiconductor wafer comprising an epitaxial semiconductor layer sequence with a plurality of chip regions is provided. The epitaxial semiconductor layer sequence is arranged on a growth substrate and a sacrificial layer is arranged at least between the chip regions and the growth substrate. For example, the epitaxial semiconductor layer sequence is epitaxially grown on the growth substrate. Particularly, the sacrificial layer and the epitaxial semiconductor layer sequence are both epitaxially grown on the growth substrate above each other. In other words, the sacrificial layer is first epitaxially grown on the growth substrate and then the epitaxial semiconductor layer sequence is epitaxially grown on the sacrificial layer. It is also possible that there are further semiconductor layers arranged between the chip regions and the growth substrate. Further, the sacrificial layer can extend completely over the growth substrate or only partially. For example, the sacrificial layer is only formed in places over the growth substrate, particularly only between the chip regions and the growth substrate.

Particularly, the chip regions of the epitaxial semiconductor layer sequence comprise active zones generating electromagnetic radiation during operation of the finished semiconductor chips, the active zones being arranged between an n-doped epitaxial semiconductor layer and a p-doped epitaxial semiconductor layer.

According to a further embodiment of the method, the epitaxial semiconductor layer sequence comprises or consists of one or several III/V compound semiconductor materials, particularly nitride semiconductor compound materials. Nitride semiconductor compound materials are semiconductor compound materials containing nitrogen, such as the materials from the system InₓAl_{y}Ga_{1-x-y}N with 0≤x≤1, 0≤y≤1 and x+y≤1.

According to a further embodiment of the method, a carrier wafer is provided. The carrier wafer is intended to be partially comprised by the finished semiconductor chips for mechanical stabilization. For example, the carrier wafer comprises or consist of silicon or a ceramic. The carrier wafer can be electrically isolating or electrically conductive. If the carrier wafer comprises a semiconductor material, such as silicon, the carrier wafer can be doped or undoped. The carrier wafer can be electrically insulating or electrically conductive.

According to a further embodiment of the method, the functional semiconductor wafer is bonded to the carrier wafer such that a wafer compound is achieved.

According to a further embodiment of the method, grooves are generated between the chip regions through the growth substrate and the sacrificial layer such that the sacrificial layer is accessible through the grooves. Particularly, the grooves form a grid between the chip regions and correspond at least partially with separation lines along which the semiconductor chips are separated at a later stage. For example, the grooves penetrate the functional semiconductor wafer completely and the carrier wafer partially. Particularly, the wafer compound is connected at least partially by the carrier wafer after generating the grooves. Between two directly adjacent grooves one or more rows of chip regions can be arranged. For example, the rows of chip regions can be separated from each other by mesas not penetrating the growth substrate.

According to a further embodiment of the method, the wafer compound and a second ECE contact (“ECE” short for “electrochemical etching”) are arranged in an electrochemical etchant. For example, the first ECE is located on the wafer compound and particularly on the carrier wafer. The second ECE contact is, for example, a second electrode locally separated from the wafer compound. The electrochemical etchant is particularly configured for etching the material of the sacrificial layer, if an ECE voltage is applied between the first ECE contact on the carrier wafer and the second ECE contact in the electrochemical etchant.

According to a further embodiment of the method, the sacrificial layer is electrochemically etched by applying the ECE voltage between the first ECE contact and the second ECE contact. Particularly, the first ECE contact is electrically conductively connected to the sacrificial layer to be etched such that electrical current flows between the first ECE contact and the sacrificial layer. Particularly, direct voltage is applied as the ECE voltage. For example, the ECE voltage lies between 1 Volt and 50 Volt, limits inclusive.

Particularly preferably, an electrical path of the electrical current flowing between the first ECE contact and the sacrificial layer, if the ECE voltage applied, is completely electrically isolated against the electrochemical etchant. In such a way, undesired parasitic electrochemical etching of material not intended for removal during the electrochemical etching is at least reduced.

According to a preferred embodiment, the method comprises the following steps:
providing the functional semiconductor wafer comprising the epitaxial semiconductor layer sequence with the plurality of chip regions, wherein the epitaxial semiconductor layer sequence is arranged on the growth substrate and the sacrificial layer is arranged at least between the chip regions and the growth substrate,
providing the carrier wafer,
bonding the functional semiconductor wafer to the carrier wafer such that the wafer compound is achieved,
generating the grooves between the chip regions through the growth substrate and the sacrificial layer such that the sacrificial layer is accessible through the grooves,
arranging the wafer compound and the second ECE contact in the electrochemical etchant,
electrochemical etching the sacrificial layer by applying the ECE voltage between a first ECE contact and the second ECE contact.

Particularly, the steps are conducted in the given order. Preferably, the grooves are generated after bonding the functional semiconductor wafer to the carrier wafer.

According to a further embodiment of the method, the growth substrate is removed. For example, the growth substrate is removed from the wafer compound by a tape lift-off. During the tape lift-off a tape is adhered to a freely accessible main surface of the growth substrate and peeled off such that the grow substrate adhered to the tape is separated from the wafer compound.

According to a further embodiment of the method, the wafer compound is singulated into a plurality of separated semiconductor chips along separation lines. The separation lines correspond at least with some of the grooves introduced in the wafer compound. Also, the mesas between the chip regions can at least partially correspond to the separation lines.

Particularly, the present method takes place as a batch process on wafer level manufacturing a plurality of semiconductor chips in parallel. Particularly, the epitaxial semiconductor layer sequence and the sacrificial layer are provided as a part of a wafer with a diameter of several inches. Particularly, the sacrificial layer is at present removed on waver level from the wafer compound. In other words, the sacrificial layer is removed as part of the wafer compound, which is singulated in separate semiconductor chips at a later stage. A batch process on wafer level particularly has the advantage of reduced process time.

According to a further embodiment of the method, the chip regions are electrically isolated against the ECE voltage, preferably completely. Particularly, sensitive semiconductor structures of the chip regions, for example multi-quantum wells of the active zones as well as p-contacts and n-contacts, are protected against parasitic electrochemical etching in such a way.

According to a further embodiment of the method, the carrier wafer has a larger diameter than the functional semiconductor wafer. In such a way, it is possible not to introduce the first ECE contact provided on the carrier wafer into the electrochemical etchant, while the functional semiconductor wafer is completely positioned in the electrochemical etchant by adjusting a filling level of the electrochemical etching. For example, the functional semiconductor wafer has a diameter between 2 and 6 inches, limits inclusive, while the carrier wafer has a diameter between 8 and 20 inches, limits inclusive. For example, the functional semiconductor wafer has a diameter of 2 inches, while the carrier wafer has a diameter of 4 inches or 6 inches or 8 inches. For example, the diameter of the carrier wafer is as large that more than one functional semiconductor wafer can be bonded to the carrier wafer.

According to a further embodiment of the method, at least one further electrical contact on the functional semiconductor wafer is electrically conductively connected to the first ECE contact on the carrier wafer during bonding. Particularly, the further electrical contact comprises a chip region covered at least partially with an electrically conductive layer. For example, the electrically conductive layer partially or completely covers the surface of the chip region. Particularly preferably, the functional semiconductor wafer comprises in a central region a plurality of chip regions being equally embodied. The plurality of chip regions in the central region of the functional semiconductor wafer are intended and configured to be part of a finished semiconductor chip. Particularly, chip regions in a boundary region of the functional semiconductor wafer are embodied as an electrical contact and covered by the electrically conductive layer. Particularly preferably, between the electrically conductive layer and the chip regions, an electrically insulating layer is arranged in order to electrically insulate the chips regions from the electrically conductive layer.

According to a further embodiment of the method, the further electrical contact of the functional semiconductor wafer is laterally embedded in a dielectric bonding material, preferably completely. In such a way electrical isolation of the chip regions against the ECE voltage in the central region of the functional semiconductor wafer can be enhanced. The dielectric bonding material is, for example, a polymer material such as a photoresist or benzocyclobutene (BCB).

According to a further embodiment of the method, the bonding of the functional semiconductor wafer to the carrier wafer comprises connecting metallic bond pads over the chip regions to metallic mounting areas of the carrier wafer. Particularly, the chip regions are electrically isolated from the metallic bond pads by the insulating layer. In other words, there are metallic bond pads arranged over the chip regions of the functional semiconductor wafer, which are electrically isolated from the chip regions by the insulating layer. The insulating layer comprises or consists, for example, of SiO2 or SiN or a combination of these materials.

For example, there is a metal layer over a main surface of the carrier wafer, the metal layer comprising the metallic mounting areas. Preferably, the metal layer extends continuously over the central region of the carrier wafer. For example, the metal layer comprises protrusions and end faces of the protrusions form the metallic mounting areas. For example, the end faces of the protrusions are connected to the metallic bond pads during the bonding process. The metallic bond pads and the metallic mounting areas particularly preferably comprise the same material or consist of the same material. Particularly, the metallic mounting areas and/or the metallic bond pads comprise or consist of one of the following metals: gold, silver, platinum, indium, tin.

For example, a dielectric layer is arranged between the metal layer and the carrier wafer. The dielectric layer particularly preferably prevents a current flow during electrochemical etching from the carrier wafer through the metallic mounting areas. In this way, parasitic electrochemical etching can be avoided, particularly in the case that the carrier wafer is electrically conductive.

According to a further embodiment of the method, at least two grooves completely penetrate the functional semiconductor wafer in a lateral direction. The lateral direction lies within a main extension plane of the functional semiconductor wafer. In this way, at least two completely separated parts of the functional semiconductor wafer are generated. In that case, each part of the functional semiconductor wafer comprises a further electrical contact electrically conductively connected to the first ECE contact on the carrier wafer, for example by a conductor track. If the functional semiconductor wafer is divided into completely separated parts by the grooves, each part of the functional semiconductor wafer is preferably provided with at least one further electrical contact in order to provide all parts of the functional semiconductor wafer with electrical current during the electrochemical etching.

According to a further embodiment of the method, each chip region comprises an n-contact and a p-contact. Particularly preferably, the n-contact and/or the p-contact are metallic. Furthermore, at least one of the n-contact and the p-contact is not in direct contact with the electrochemical etchant during electrochemical etching. Preferably, both, the n-contact and the p-contact, are not in direct contact with the electrochemical etchant during electrochemical etching. Particularly, at least one of the n-contact and the p-contact is electrically isolated against the ECE voltage. Preferably, both, the n-contact and the p-contact are electrically isolated against the ECE voltage. In such a way, the chip regions comprising the n-contacts and the p-contacts are not provided with electrical current during electrochemical etching such that parasitic electrochemical etching is at least reduced.

According to a further embodiment of the method, at least two functional semiconductor wafers are bonded to the carrier wafer. Particularly, each functional semiconductor wafer comprises at least one further electrical contact electrically conductively connected to the first ECE contact on the carrier wafer. Providing the carrier wafer with more than one functional semiconductor wafer allows the production of a large number of semiconductor chips in parallel. However, it is necessary to provide each functional semiconductor wafer with at least one respective further electrical contact.

If more than one functional semiconductor wafers are bonded to a common carrier wafer, the carrier wafer has to be large enough. Particularly, in the case of two functional semiconductor wafers, the carrier wafer has to be at least twice as large as the functional semiconductor wafers. In the case of N functional semiconductor wafers, the carrier wafer has to be N times larger than the two functional semiconductor wafers.

According to a further embodiment of the method, the sacrificial layer comprises or consists of a highly n-doped semiconductor material, particularly of a highly n-doped nitride semiconductor compound material. Particularly, a highly n-doped nitride semiconductor compound material has a higher etching rate in the electrochemical etchant than a lower doped or non-doped nitride semiconductor compound material. Particularly, the active radiation generating zones of the chip regions, are low, non-doped or only unintendedly doped. Therefore, the sacrificial layer comprising a highly n-doped semiconductor material can be electrochemically etched against the chip regions. Particularly, the highly n-doped semiconductor material has a dopant concentration of at least 1018/cm3. If the active radiation generating zones of the chip regions are n-doped, they have to be protected during electrochemical etching.

According to a further embodiment of the method, an etch stop layer is arranged between the sacrificial layer and the chip regions. Particularly, the etch stop layer has a smaller etching rate in the electrochemical etchant than the sacrificial layer. For example, the etch stop layer has an etching rate in the electrochemical etchant of one magnitude of order smaller than the sacrificial layer. In such a way the chip regions are protected against material decomposition during electrochemical etching. Preferably, the etch stop layer is in direct contact with the sacrificial layer. Also, the etch stop layer can be in direct contact with the chip regions. For example, particularly if the chip regions are based on, or consist of, materials of a nitride semiconductor compound material, the etch stop layer comprises, or consist of, AlN or AlInN.

According to a further embodiment, the grooves are formed by at least one of the following methods: sawing, reactive ion etching (RIE), laser grooving. It is also possible that one or more of these methods are combined or conducted successively in order to form the grooves.

According to a further embodiment of the method, the growth substrate comprises or consists of GaN or sapphire. Particularly, these materials are suited as growth substrate for epitaxial growth of an epitaxial semiconductor layer sequence based on a nitride semiconductor compound material.

According to a further embodiment of the method, the wafer compound is arranged in a vertical direction in the electrochemical etchant. At present, the vertical direction particularly runs parallel to the direction of gravity. If the wafer compound is arranged in a vertical direction, gas bubbles generated during electrochemical etching by decomposition of the etched material can ascend easily from the wafer compound within the liquid electrochemical etchant. Further, vertically ascendant gas bubbles can improve exchange of electrochemical etchant due to turbulences.

According to a further embodiment of the method, only one of the first ECE contact and the second ECE contact is in contact with the electrochemical etchant. For example, the first ECE contact on the wafer compound is not in contact with the electrochemical etchant when the wafer compound and the second ECE contact are arranged in the electrochemical etchant. This is particularly the case, when the wafer compound is arranged vertically in the electrochemical etchant and the first ECE contact is arranged in the edge area of the carrier wafer. If only one ECE contact is arranged in the electrochemical etchant, electric isolation between the first ECE contact and the second ECE contact can be achieved easily.

According to a further embodiment of the method, the wafer compound is arranged in a horizontal direction in the electrochemical etchant. Particularly, the horizontal direction is perpendicular to the vertical direction. In other words, the horizontal direction is perpendicular to the force of gravity.

According to a further embodiment of the method, both, the first ECE contact and the second ECE contact are arranged within the electrochemical etchant, when the wafer compound is arranged within the electrochemical etchant. This is particularly the case, if the wafer compound is arranged in the horizontal direction in the electrochemical etchant. In order to achieve electrical isolation between the first ECE contact and the second ECE contact, a sealing rim can be used. Particularly, the first ECE contact is completely encapsulated within a wafer holder comprising the sealing rim.

Preferably, the elements forming the electrical path for the electrical current between the first ECE contact and the sacrificial layer, such as the further electrical contact(s), the conductive tracks and the growth substrate are not electrically conductively connected to the electrochemical etchant, but only to the sacrificial layer.

According to a further embodiment of the method, the functional semiconductor wafer comprises at least one further electrical contact formed as a ring surrounding the chip regions and electrically conductively connected to the first ECE contact on the carrier wafer.

According to a further embodiment of the method, the functional semiconductor wafer comprises a ring-shaped barrier arranged between the chip regions and the further electrical contact, particularly if the wafer compound is arranged in a horizontal direction within the electrochemical etchant.

With the described method, for example, semiconductor chips embodied as an edge emitting laser device or a VCSEL (short for “vertical cavity surface emitting laser”) can be manufactured. Furthermore, LED chips, particularly, UV-LED chips can be achieved.

The semiconductor chips manufactured with the method can be used, for example, in augmented reality applications as well as in a micro-AFS (short for “microstructured adaptive front lighting system”).

Particularly preferably, with the present method and with the wafer designs of the functional semiconductor wafer as well as of the carrier wafer, it is possible to remove the sacrificial layer, and consequently the growth substrate, on wafer level by a simplified method using electrochemical etching.

### BRIEF DESCRIPTION OF THE DRAWINGS

Further advantageous embodiments and developments of the method for manufacturing a plurality of semiconductor chips result from the exemplary embodiments described below in connection with the Figures.

FIGS. 1 to 7 show schematic views of stages of a method for manufacturing a plurality of semiconductor chips according to an exemplary embodiment.

FIGS. 8 to 10 show schematic views of stages of a method for manufacturing a plurality of semiconductor chips according to a further exemplary embodiment.

FIGS. 11 to 14 show schematic views of stages of methods for manufacturing a plurality of semiconductor chips according several exemplary embodiments.

FIGS. 15 to 25 show schematic views of stages of a method for manufacturing a plurality of semiconductor chips according to a further exemplary embodiment.

FIGS. 26 to 28 show schematic views of stages of a method for manufacturing a plurality of semiconductor chips according to a further exemplary embodiment.

FIGS. 29 to 31 show schematic views of stages of a method for manufacturing a plurality of semiconductor chips according to a further exemplary embodiment.

FIGS. 32 to 35 show schematic views of stages of a method for manufacturing a plurality of semiconductor chips according to a further exemplary embodiment.

FIGS. 36 to 38 show schematic views of stages of a method for manufacturing a plurality of semiconductor chips according to a further exemplary embodiment.

FIG. 39 shows a schematic view of a stage of a method for manufacturing a plurality of semiconductor chips according to a further exemplary embodiment.

FIGS. 40 to 41 show schematic views of stages of a method for manufacturing a plurality of semiconductor chips according to a further exemplary embodiment.

FIGS. 42 to 43 show schematic views of stages of a method for manufacturing a plurality of semiconductor chips according to a further exemplary embodiment.

FIG. 44 shows a schematic view of a stage of a method for manufacturing a plurality of semiconductor chips according to a further exemplary embodiment.

Equal or similar elements as well as elements of equal function are designated with the same reference signs in the Figures. The Figures and the proportions of the elements shown in the Figures are not regarded as being shown to scale. Rather, single elements, in particular layers, can be shown exaggerated in magnitude for the sake of better presentation and/or better understanding.

### DETAILED DESCRIPTION OF ILLUSTRATIVE EMBODIMENTS

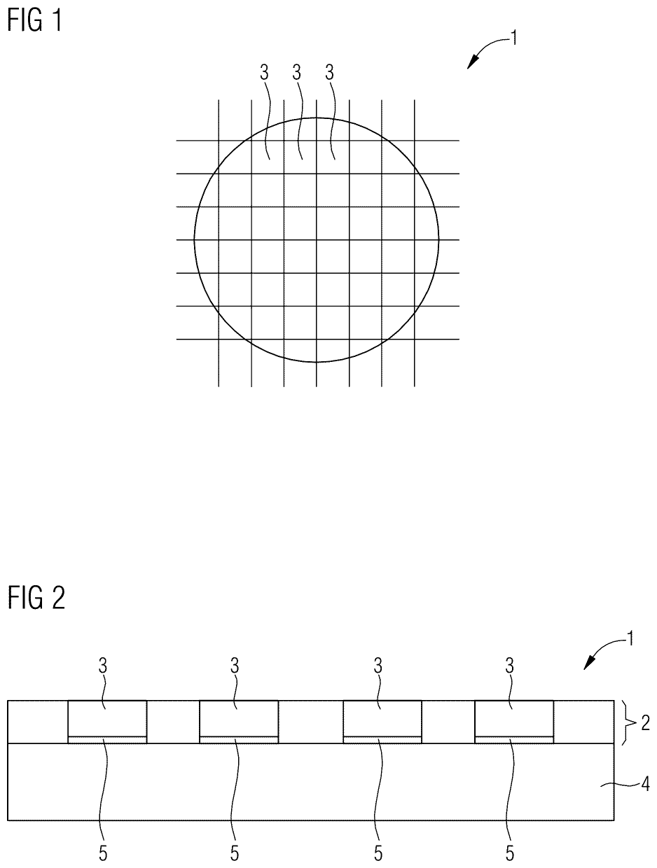

According to the method of the exemplary embodiment of FIGS. 1 to 7, a functional semiconductor wafer 1 is provided. The functional semiconductor wafer 1 is schematically shown in FIG. 1 in plan view, while FIG. 2 shows a sectional view of the functional semiconductor wafer 1 of FIG. 1.

The functional semiconductor wafer 1 comprises an epitaxial semiconductor layer sequence 2 with a plurality of chip regions 3. The epitaxial semiconductor layer sequence 2 is arranged on a growth substrate 4 and a sacrificial layer 5 is arranged between the chip regions 3 and the growth substrate 4. Particularly, the sacrificial layer 5 is only arranged between the chip regions 3 and the growth substrate 4, while regions between the chip regions 3 are free of the sacrificial layer 5.

At present, the epitaxial semiconductor layer sequence 2 is based on a nitride semiconductor compound material, while the growth substrate 4 comprises or consists of GaN, AIN or sapphire. The sacrificial layer 5 comprises or consists of a highly n-doped nitride semiconductor compound material.

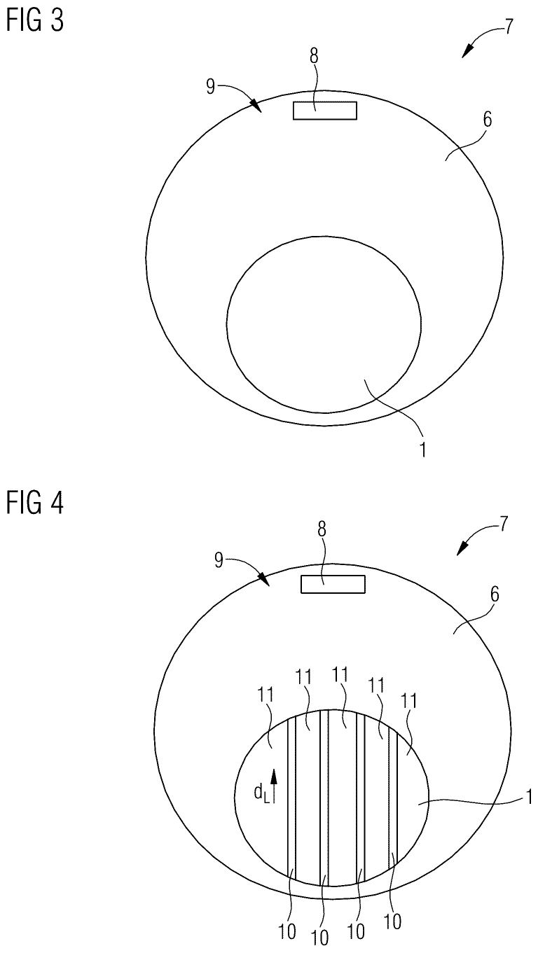

Further, a carrier wafer 6 is provided. The carrier wafer 6 consists or comprises silicon or a ceramic, for example. At present, the carrier wafer 6 has a larger diameter than the functional semiconductor wafer 1. The functional semiconductor wafer 1 is bonded to the carrier wafer 6 such that a wafer compound 7 is achieved (FIG. 3). The functional semiconductor wafer 1 is arranged offset to a center point of the carrier wafer 6. Furthermore, the carrier wafer 6 comprises a first ECE contact 8 arranged in an edge area 9 of the carrier wafer 6. The first ECE contact 8 is, for example, a metallic structure, at present with a rectangular geometry.

In a further step, grooves 10 are generated between the chip regions, for example by sawing. The grooves 10 penetrate at least through the growth substrate 4 and the sacrificial layer 5 such that the sacrificial layer 5 is accessible through the grooves 10. The grooves 10 extend in a lateral direction DL lying within a main extension plane of the functional semiconductor wafer 1. The grooves 10 are arranged parallel to each other. Furthermore, the grooves 10 divide the functional semiconductor wafer 1 into parts 11 completely separated from each other seen in plan view on a main surface of the functional semiconductor wafer 1 (FIG. 4).

The wafer compound 7 comprising the carrier wafer 6 and the functional semiconductor wafer 1 is arranged within a liquid electrochemical etchant 12 provided in a vessel 13 (FIG. 5). The electrochemical etchant 12 is, for example, nitridic etchant, such as HNO3. Further, a second ECE contact 14 is arranged in the electrochemical etchant 12. The first ECE contact 8 on the wafer compound 7 is not in contact with the electrochemical etchant 12. An ECE voltage V is applied between the first ECE contact 8 and the second ECE contact 14 such that electrochemical etching takes place within the electrochemical etchant 12. Particularly, the sacrificial layer 5 is etched during electrochemical etching such that the material of the sacrificial layer 5 is decomposed and gas bubbles 15 are generated.

The wafer compound 7 is arranged in a vertical direction DV running parallel to the force of gravity in the electrochemical etchant 12 such that the gas bubbles 15 ascend to an interface of electrochemical etchant 12 with the surrounding gaseous medium, such as air. The movement of the gas bubbles 15 within the liquid electrochemical etchant 12 causes turbulences, leading to enhanced exchange of electrochemical etchant 12 at the place of the material of the sacrificial layer 5 to be decomposed, enhancing homogeneity and efficiency of the etchant process. Electrochemical etching can take place starting from side walls of the grooves 10.

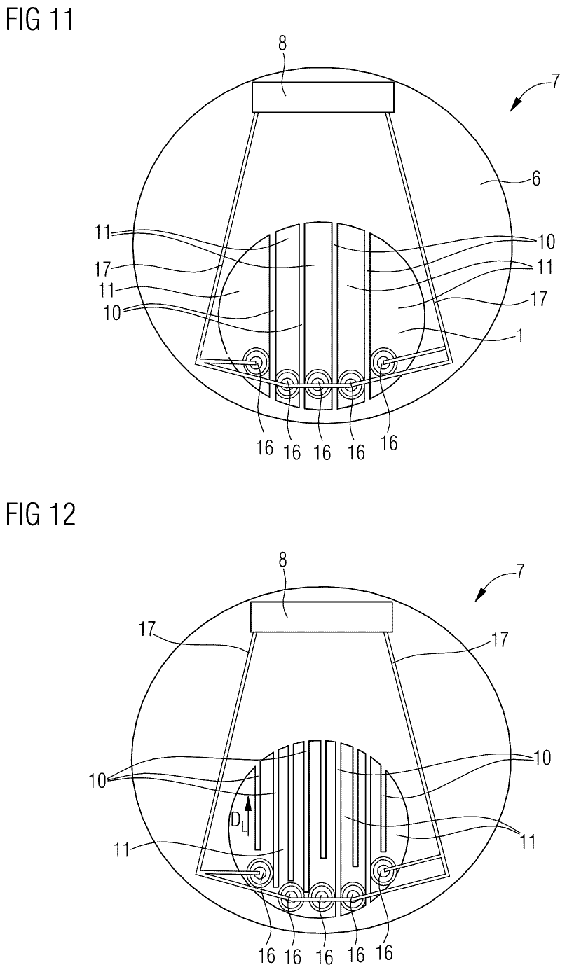

The first ECE contact 8 on the carrier wafer 6 is connected to further electrical contacts 16 on the parts 11 of the functional semiconductor wafer 1 by metallic strip-shaped conductor tracks 17, which are shown in FIG. 11. The conductor tracks 17 are particularly isolated from the carrier wafer 1 by a dielectric layer 18 arranged between the conductor tracks 17 and the carrier wafer 6 (FIG. 5). Further, the conductor tracks 17 are covered by an isolator layer 19 electrically isolating the conductor tracks 17 against the electrochemical etchant 12. The isolator layer 19 can for example, comprise or consist of a photoresist or of a dielectric material.

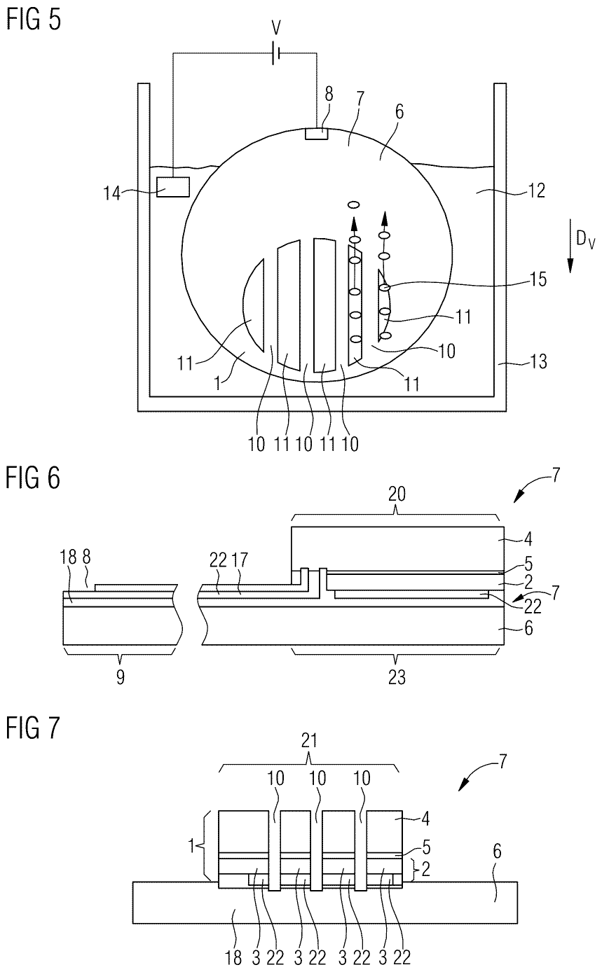

FIG. 6 schematically shows a boundary region 20 of the functional semiconductor wafer 1 within the wafer compound 7, while FIG. 7 shows a central region 21 of the functional semiconductor wafer 1 with chip regions 3 intended to be part of finished semiconductor chips.

On the carrier wafer 6 the dielectric layer 18 is arranged covered by a metal layer 22. The metal layer extends in a central area 23 and the edge area 9 of the carrier wafer 6 (FIGS. 6 and 7). In the edge area 9, the metal layer 22 forms a conductor track 17 connecting a further electrical contact 16 of the functional semiconductor wafer 1 with the first ECE contact 8 on the carrier wafer 6. In the edge area 9, the metal layer 22 is covered by the isolator layer 19 in order to protect the metallic material of the metal layer 22 from the electrochemical etchant 12.

The chip regions 3 in the central region 21 of the functional semiconductor wafer 1 are configured and intended to be part of the finished semiconductor chips. Between the chip regions 3 and a growth substrate 4 of the functional semiconductor wafer 1 a sacrificial layer 5 is arranged.

The grooves 10 between the chip regions 3 also penetrate the carrier wafer 6 partially (FIG. 7). A spacing between the grooves 10 can be identical to a spacing between directly adjacent chip regions 3. Further, the spacing between the grooves 10 can be larger than a spacing between directly adjacent chip regions 3. Particularly, the grooves 10 correspond to separation lines 27 along which separation of the wafer compound 7 in separated semiconductor chips takes place.

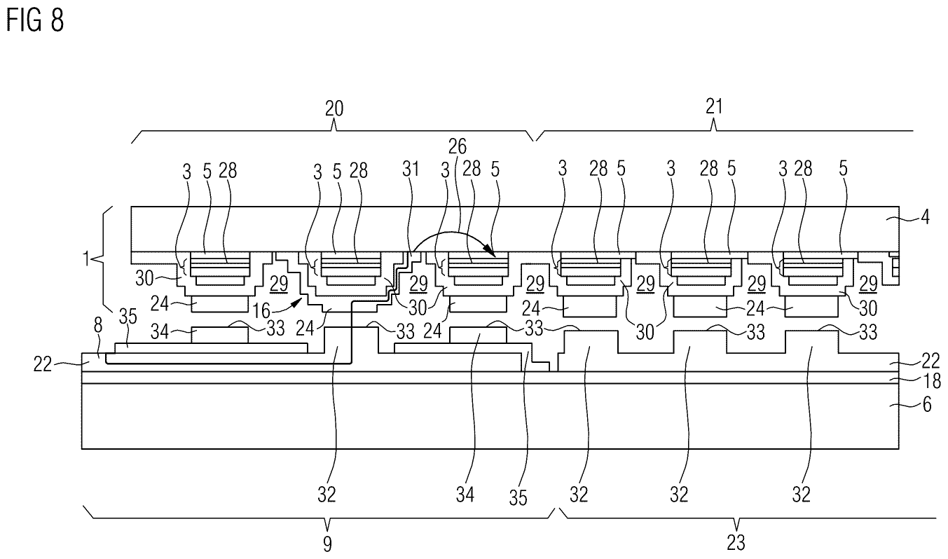

With the help of the method of the exemplary embodiment of FIGS. 8 to 10, the bonding of the carrier wafer 6 to the functional semiconductor wafer 1 is explained in further detail. Particularly, wafer designs of the functional semiconductor wafer 1 and the carrier wafer 6 advantageous for bonding and providing an advantageous current flow during later electrochemical etching is explained in further detail.

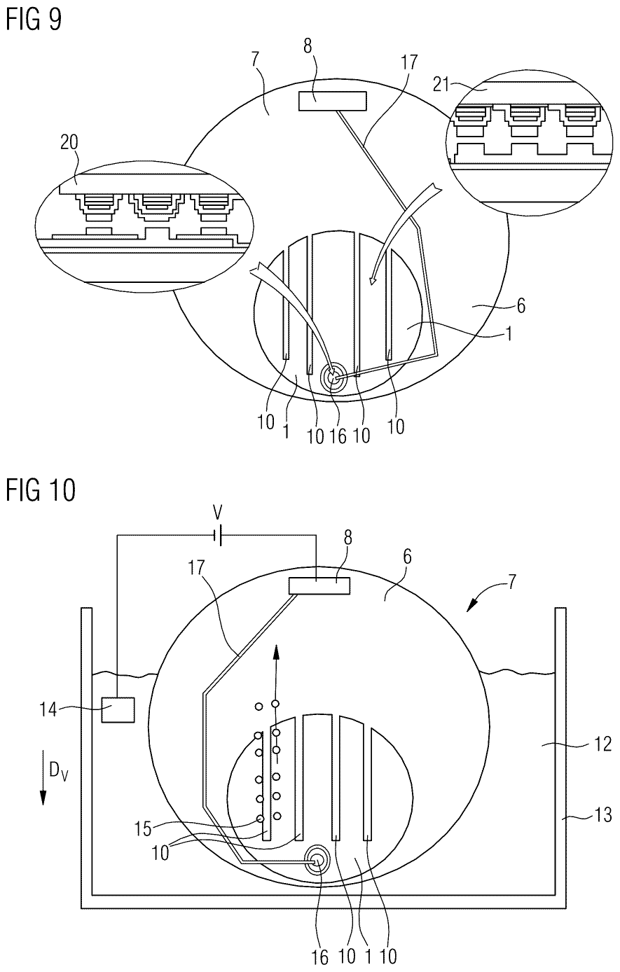

The functional semiconductor wafer 1 has a central region 21 with chip regions 3 intended to be comprised by finished semiconductor chips, while a boundary region 20 of the functional semiconductor wafer 1 adjacent to the central region 21 comprises chip regions 3 further modified for bonding the functional semiconductor wafer 1 to the carrier wafer 6 and particularly for forming a feed through for an electrical path 26 (FIGS. 8 and 9).

The chip regions 3 comprises an epitaxial semiconductor layer sequence 2 with active zones 28 configured for generating electromagnetic radiation during operation of the finished semiconductor chips. The chip regions 3 are separated from each other by mesas 29, wherein the mesas 29 do not penetrate a growth substrate 4. Particularly, the chip regions 3 are separated in rows by the mesas 29. Further, there is a sacrificial layer 5 arranged between the chip regions 3 and a growth substrate onto which the chip regions 3 are arranged. Over the chips regions 3 in the central region 21 and in the boundary region 20, metallic bond pads 24 are arranged. The metallic bond pads 24 over the chip regions 3 of the functional semiconductor wafer 1 are electrically isolated from the chip regions 3 by an insulating layer 30 arranged between the metallic bond pads 24 and the chip regions 3. Particularly, the isolating layer 30 electrically isolates the growth substrate 4 from the metallic bond pads 24.

The boundary region 20 of the functional semiconductor wafer 1 comprises three rows of chip regions 3 not intended to be part of finished semiconductor chips but modified to form a further electrical contact 16. A row of chip regions 3 arranged between two further rows of chip regions 3 in the boundary region 20 is provided with an electrically conductive layer 31, wherein the insulating layer 30 is arranged between the electrically conductive layer 31 and the chip regions. The chip regions 3 are completely covered by the electrically conductive layer 31. Particularly, the electrically conductive layer 31 is in direct contact with the growth substrate 4 of the functional semiconductor wafer 1. The further electrical contact 16 is after bonding protected from electrochemical etchant 12 by the both directly adjacent rows of chip regions 3. For example, the electrically conductive layer 31 is a metallic layer. Instead of a row, the chip regions 3 can be arranged in a ring-shaped geometry.

The carrier wafer 6 has a central area 23 to be bonded to the central region 21 of the functional semiconductor wafer 1 during bonding. Further, the carrier wafer 6 has an edge area 9, which is mechanically stable and electrically conductively connected to a further electrical contact 16 of the functional semiconductor wafer 1 during bonding. Further, the edge area 9 comprises at least one conductor track 17 and a first ECE contact 8. The conductor track 17 electrically connects the first ECE contact 8 and the further electrical contact 16 electrically conductive after bonding.

In the central region 21 of the carrier wafer 6 a metal layer 22 having protrusions 32 with metallic mounting areas 33 intended to be bonded to the metallic bond pads 24 over the chip regions 3 of the functional semiconductor wafer 1 are arranged. The metal layer 22 is electrically isolated from the carrier wafer 6 by a dielectric layer 18.

The metal layer 22 and the dielectric layer 18 also extends in the edge area 9 of the carrier wafer 6. Further, the metal layer 22 in the edge area 9 comprises a further metallic mounting area 33 being part of a protrusion 32. The protrusion 32 of the metallic mounting area 33 in the edge area 9 of the carrier wafer 6 is connected to the electrically conductive layer 31 over the chip region 3 in the boundary region 20 of the functional semiconductor wafer 1 during bonding of the functional semiconductor wafer 1 and the carrier wafer 6 and forms an electrical feedthrough to the growth substrate 4 and the sacrificial layer 5 for the electrical current applied during electrochemical etching. The protrusion 32 of the metallic mounting area 33 in the edge area 9 of the carrier wafer 6 is arranged between two metallic connection pads 34 providing also metallic mounting areas 33 for connection to metallic bond pads 24 of the functional semiconductor wafer 1 during bonding. The two metallic connection pads 24 are electrically isolated against the underlying chip regions 3 by the insulating layer 30.

After bonding the functional semiconductor wafer 1 to the carrier wafer 6, grooves 10 are inserted into the functional semiconductor wafer between the chip regions through the growth substrate and the sacrificial layer such that the sacrificial layer is accessible through the grooves (FIG. 9).

The grooves 10 generated in the functional semiconductor wafer 1 between the chip regions 3 do not separate the functional semiconductor wafer 1 completely in a lateral direction DL into different parts 11. Therefore, one further electrical contact 16 on the wafer compound 7 is sufficient to provide the whole functional semiconductor wafer 1 with electrical current from the first ECE contact 8 connected to the further electrical contact 16 by a conductor track 17.

The wafer compound 7 formed by bonding the carrier wafer 6 and the functional semiconductor wafer 1 is arranged in an electrochemical etchant 12 and an ECE voltage V is applied between the first ECE contact 8 and a second ECE contact 14, the second ECE contact 14 being also arranged in the electrochemical etchant 12 (FIG. 10). After applying the ECE voltage V between the first ECE contact 8 and the second ECE contact 14, electrochemical etching takes place wherein gas bubbles 15 are produced by decomposing the material of the sacrificial layer 5. Since the wafer compound 7 is arranged in a vertical direction DV parallel to the direction of gravity in the vessel 13 with the electrochemical etchant 12, the gas bubbles 15 can rise to a surface of the electrochemical etchant 12.

In contrast to the method of the exemplary embodiment of FIGS. 8 to 10, the functional semiconductor wafer 1 is completely divided into separate parts 11 by the grooves 10 according to the exemplary embodiment of FIG. 11. Each separate part 11 of the functional semiconductor wafer 1 is provided with a further electrical contact 16 being electrically conductively connected to the first ECE contact 8 in the edge area 9 of the carrier wafer 6 by respective conductor tracks 17. In such a way, the different parts 11 of the functional semiconductor wafer 1 can be supplied with electrical current during electrochemical etching.

During the method of the exemplary embodiment of FIG. 12, some grooves 10 completely divide the functional semiconductor wafer 1 in a lateral direction DL, while other grooves 10 do not completely divide the functional semiconductor wafer 1 in different parts 11. Each separate part 11 of the functional semiconductor wafer 1 is provided with a further electrical contact 16. Also, several further electrical contacts 16 are applied on a continuous part of the functional semiconductor wafer 1 further enhancing homogeneity of current flow during electrochemical etching. All further electrical contacts 16 are electrically conductively connected by conductor tracks 17 with the first ECE contact 8 on the carrier wafer 6.

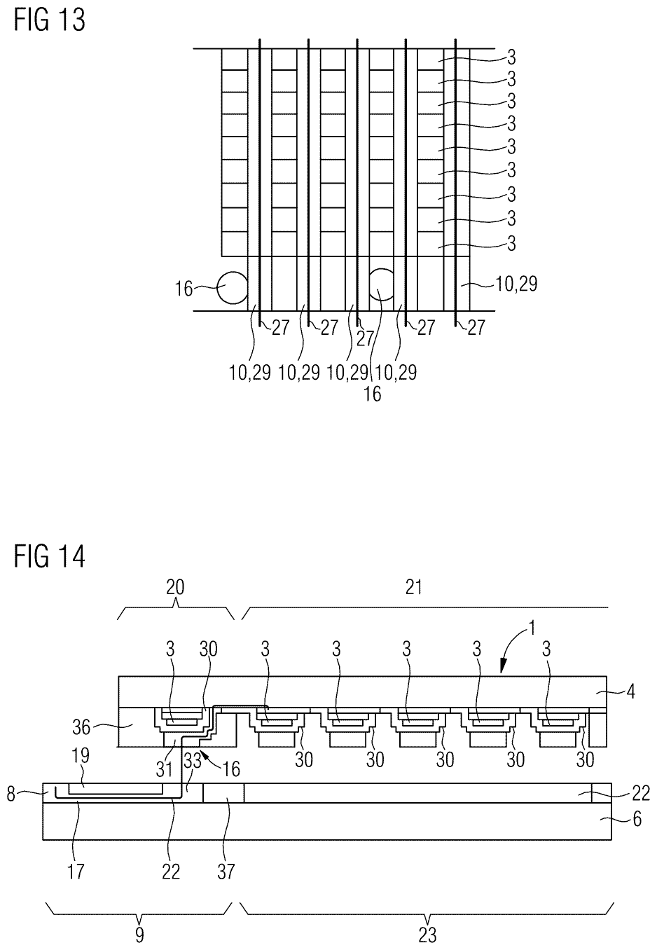

According to the method of the exemplary embodiment of FIG. 13, the chip regions 3 are separated into different columns by mesas 29. Within the mesas 29 grooves 10, also corresponding to separation lines 27, are arranged. In a boundary region 20 of the functional semiconductor wafer 1 further electrical contact 16 are arranged depending on whether the grooves 10 divide the functional semiconductor wafer 1 into separated parts 11 or not. The wafer compound 7 is divided along the separation lines 27 into single semiconductor chips.

According to the method of the exemplary embodiment of FIG. 14, a boundary region 20 of the functional semiconductor wafer 1 and an edge area 9 of the carrier wafer 6 are embodied in a different way. Particularly, a further electrical contact 16 of the functional semiconductor wafer 1 is based on a chip region 3 in the boundary region 20 covered in places with an electrically conductive layer 31. The electrically conductive layer 31 is in direct contact with a growth substrate 4. The further electrical contact 16 is laterally completely embedded in a dielectric bonding material 36.

In the edge area 9 of the carrier wafer 6 a metal layer 22 is arranged. The metal layer 22 also covers a central area 23 of the carrier wafer 6. The metal layer 22 is at present in direct contact with the carrier wafer 6. The metal layer 22 in the edge area 9 is electrically isolated against its parts in the central area 23 by an electrically isolating element 37. Further, the metal layer 22 in the edge area 9 forms a conductive track 17 covered by an isolator layer 19, wherein the isolator layer 19 leaves an electrical mounting area 33 for connection with the further electrical contact 16 during bonding freely accessible.

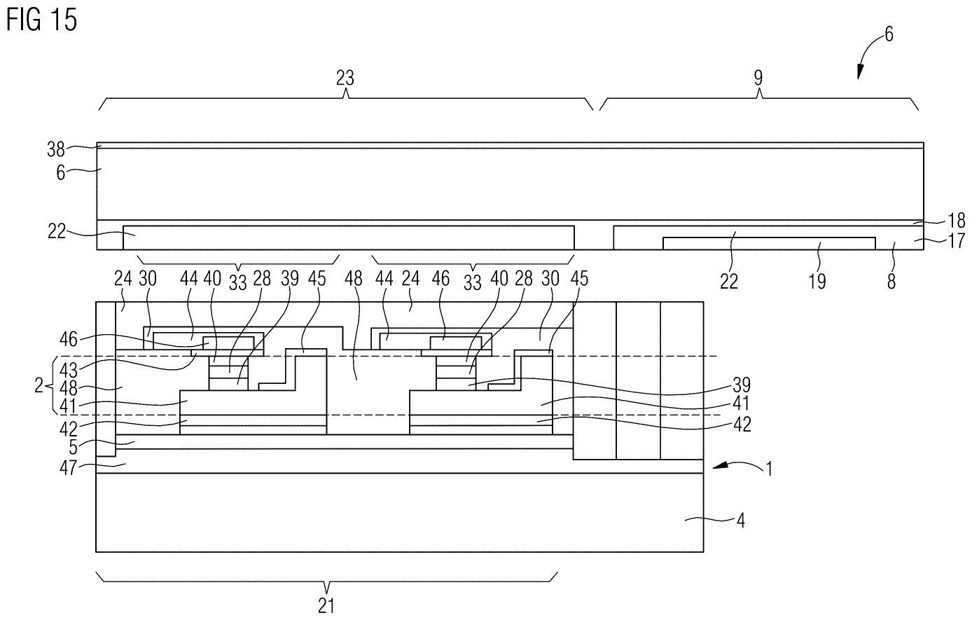

During the method of the exemplary embodiment of FIGS. 15 to 25, a carrier wafer 6 is provided (FIG. 15). On the carrier wafer 6 a dielectric layer 18 is arranged completely covering a main surface of the carrier wafer 6. On the dielectric layer 18 over a central area 23 of the main surface of the carrier wafer 6 metallic mounting areas 33 are arranged. The metallic mounting areas 33 are part of a metal layer 22. A metallic conductor track 17 is arranged in an edge area 9 of the carrier wafer 6. The metallic conductor track 17 ends a first ECE contact 8. The metallic conductor track 17 is covered by an isolator layer 19 leaving the first ECE contact 8 freely accessible. A back main surface of the carrier wafer 6 oppositely to the main surface is covered at present with a backside contact layer 38. The presence of the backside contact layer 38 is optional.

Furthermore, a functional semiconductor wafer 1 is provided (FIG. 15). The functional semiconductor wafer 1 comprises an epitaxial semiconductor layer sequence 2 with a plurality of chip regions 3, wherein in FIG. 15 only two chip regions 3 are exemplarily shown for the sake of clarity. The chip regions 3 are arranged on a GaN growth substrate 4 not intentionally doped. The chip regions 3 are embodied equally to each other in the present exemplary embodiment. Each chip region 3 comprises an n-doped semiconductor layer 39 and a p-doped semiconductor layer 40. Between the n-doped semiconductor layer 39 and the p-doped semiconductor layer 40 an active zone 28 is arranged. The active zone 28 is configured to generate electromagnetic radiation in the operation of the finished semiconductor chip.

The chip regions 3 further comprises a layer of unintentionally doped semiconductor material 41 having a thickness between and including 200 nanometer and 1000 nanometer. The layer of unintentionally doped semiconductor material 41 is in direct contact with an etch stop layer 42.

The chip regions 3 comprises further p-contact layers 43, at present comprising or consisting of ITO (short for “indium tin oxide”). The p-contact layers 43 are in direct contact with a metallic p-contact 44, which is configured for electrical connection of p-doped layers of the epitaxial semiconductor layer sequence 2. Further, the chip regions 3 comprises metallic n-contacts 45 electrically connecting n-doped layers of the epitaxial semiconductor layer sequence 2.

The chip regions 3 further comprises a first mirror layer 46, particularly a DBR mirror layer (DBR short for “distributed Bragg reflector”). The first mirror layer 46 is intended to be part of a vertical resonator of a finished semiconductor chip being a VCSEL.

Between the chip regions 3 and the growth substrate 4 a sacrificial layer 5 being highly n-doped is arranged. For example, the sacrificial layer 5 is based on a nitride semiconductor compound material and has a dopant concentration of at least 1018 cm-3. The etch stop layer 42 is arranged between the sacrificial layer 5 and the chip regions 3. The etch stop layer 42 is in direct contact with the sacrificial layer 5 and the chip regions 3. The etch stop layer 42 comprises or consists of AlN or AlInN. Further, a further n-doped semiconductor layer 47 is arranged between the sacrificial layer 5 and the growth substrate 4. The further n-doped semiconductor layer 47 is in direct contact with the sacrificial layer 5 and the growth substrate 4.

The metallic p-contact 44 and the metallic n-contact 45 are embedded in an isolation material 48 electrically insulating the metallic p-contact 44 and the metallic n-contact 45 from each other. The isolation material 48 is also arranged at side faces of the chip regions 3 and extend until the sacrificial layer 5 parallel to a growth direction of the epitaxial semiconductor layer sequence 2. The isolation material 48 electrically insulates metallic bond pads 24 arranged over the chip regions 3 from the chip regions 3.

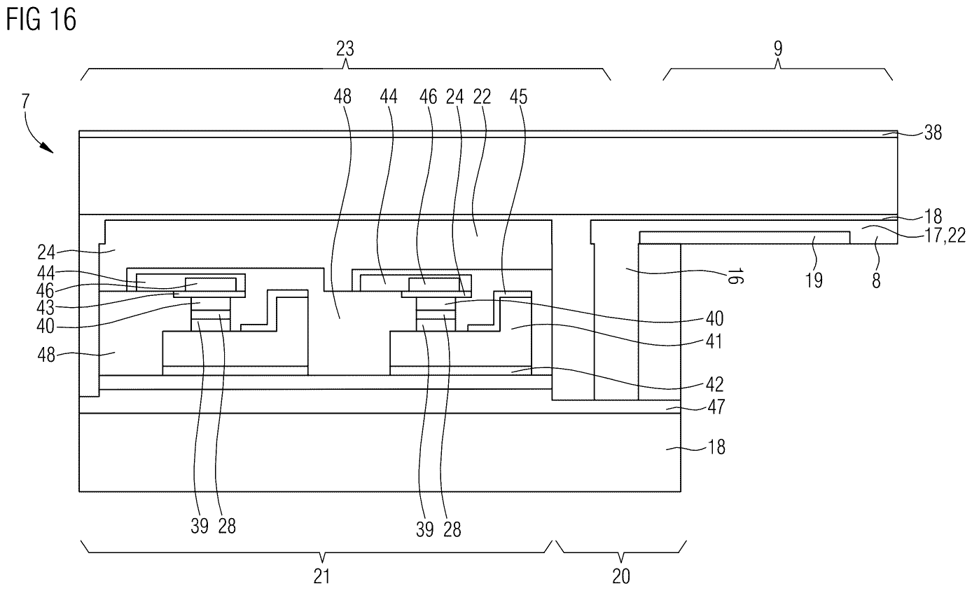

The carrier wafer 6 and the functional semiconductor wafer 1 are bonded together, particularly about the metallic mounting areas 33 of the metal layer 22 on the carrier wafer 6 and the metallic bond pads 24 over the chip regions 3 (FIG. 16). The carrier wafer 6 and the functional semiconductor wafer 1 form a wafer compound 7. At a boundary region 20 of the functional semiconductor wafer 1 a further electrical contact 16 is arranged electrically contacting the sacrificial layer 5 about the further n-doped semiconductor layer 47. It is also possible that the electrically conductive layer 31 is in direct contact with the sacrificial layer 5. The chip regions 3 can be planarized by a planarization material prior to bonding to the carrier wafer 6 (not shown).

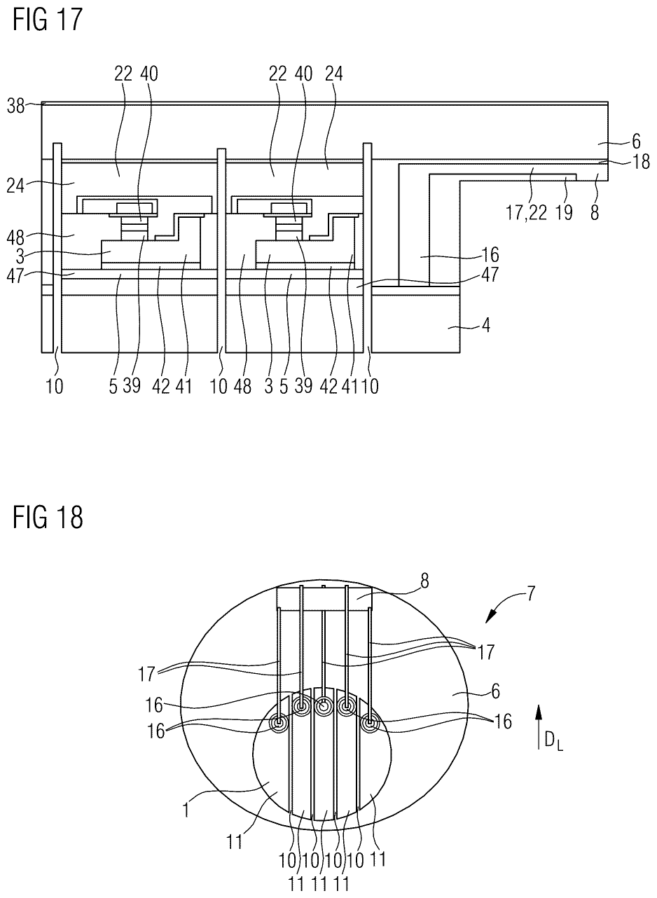

Grooves 10 are inserted between the chip regions 3 (FIG. 17). The grooves 10 completely penetrate the functional semiconductor wafer 1 and the carrier wafer 6 partially. For example, the grooves 10 extend within the carrier wafer 6 up to a depth of 20 micrometer. The sacrificial layer 5 is accessible through the grooves 10.

FIG. 18 depicting a schematic plan view on the wafer compound 7 shows that the grooves 10 completely penetrate the functional semiconductor wafer 1 in a lateral direction DL such that separated parts 11 of the functional semiconductor wafer 1 are formed. On every separated part 11 of the functional semiconductor wafer 1, a further electrical contact 16 is applied and electrically conductively connected to the first ECE contact 8 on the carrier wafer 6 via conducting tracks 17.

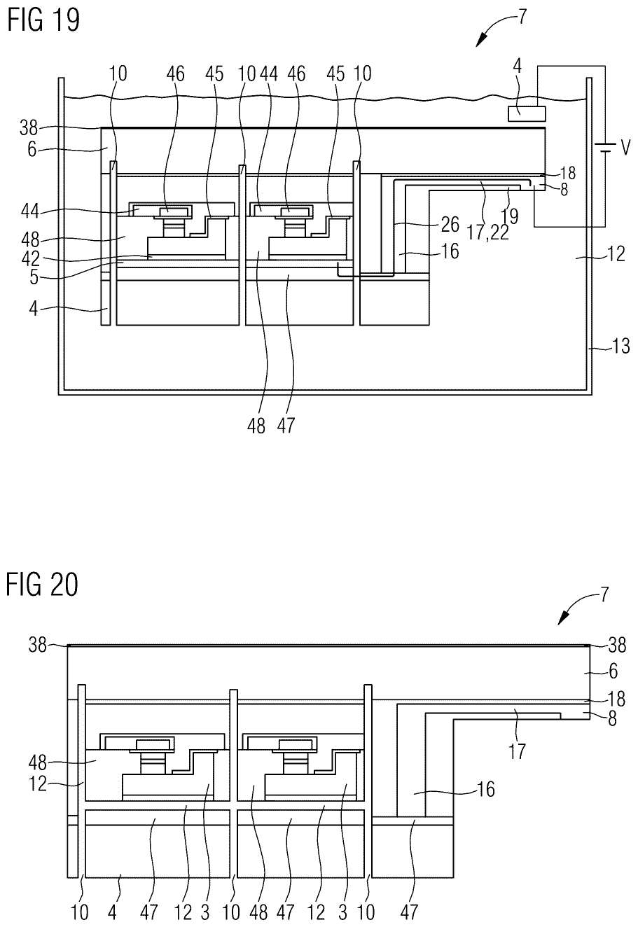

After placing the wafer compound 7 with the grooves 10 in an electrochemical etchant 12 (see FIG. 19), an ECE voltage V is applied between the first ECE contact 8 and the second ECE contact 14, as already explained in connection with FIG. 5. The electrochemical etchant 12 penetrates into the grooves 10 and reaches the sacrificial layer 5 as indicated by the arrows.

If the ECE voltage V is applied an electrical current flows from the first ECE contact 8 over the further electrical contact 16 to the sacrificial layer 5 according to an electrical path 26. During electrochemical etching the sacrificial layer 5 is decomposed and removed. By removing the sacrificial layer 5, the growth substrate 4 is detached from the wafer compound 7 (FIG. 20).

After electrochemical etching of the sacrificial layer 5 only the further electrical contact 16, the first ECE contact 8 and the conductive track 17 connecting the further electrical contact 16 and the first ECE contact 8 holds the remaining wafer compound 7, particularly over the further n-doped semiconductor layer 47. After removing the sacrificial layer 5 the ECE voltage V might be enhanced in order to also electrochemically etch the further n-doped semiconductor 47 layer in order to detach the growth substrate 4 completely. When enhancing the ECE voltage V, the further n-doped semiconductor layer 47 becomes porous and is finally dissolved.

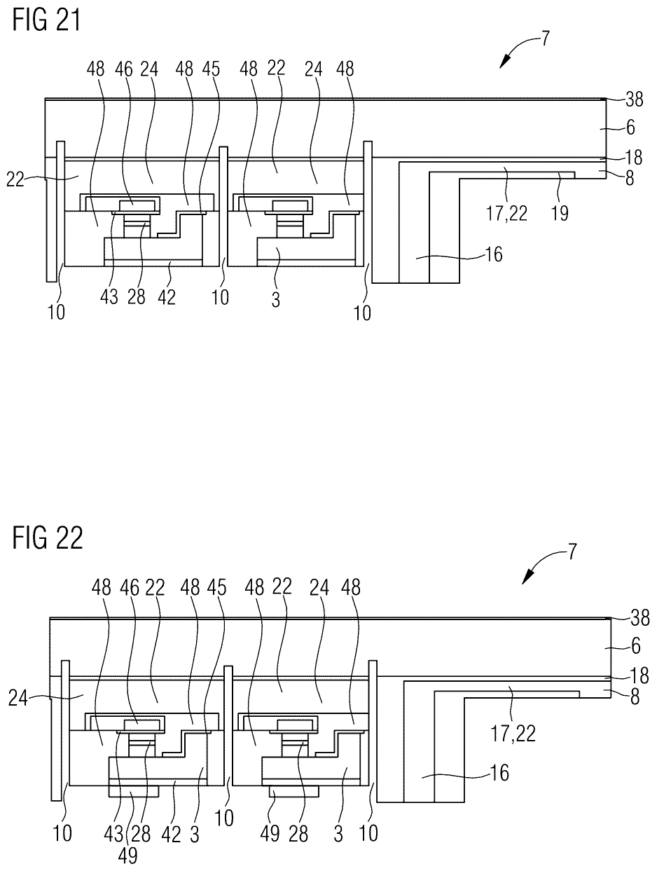

Then, the growth substrate 4 is removed from the wafer compound 7, for example by tape lift-off (FIG. 21).

A second mirror layer 49, particularly a second DBR mirror layer, is arranged over the chip regions 3 in direct contact with the etch stop layer 42 in order to form a vertical resonator together with the first DBR mirror layer in the finished semiconductor chip embodied as a VCSEL (FIG. 22).

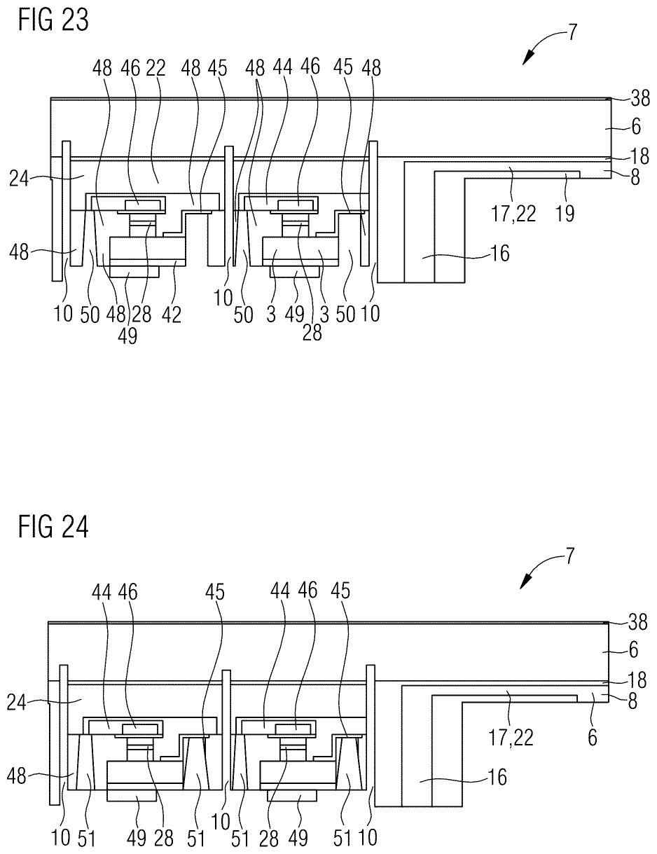

Then, cut outs 50 are formed in order to give access to the metallic p-contact 44 and the metallic n-contact 45. The cut out 50 giving access to the metallic p-contact 44 is formed within the isolation material 48, while the cut out 50 giving access to the metallic n-contact 45 is formed within the semiconductor material of the epitaxial semiconductor layer sequence 2 (see FIG. 23). The cut outs 50 are filled with a metallic material 51, particularly preferably completely, such that the metallic material 51 filling the cut outs 50 giving access to the p-contact 44 and the n-contact 45 is accessible at a front side of the chip regions 3 (FIG. 24). The metallic p-contact 44 is after filling the cut outs 50 in direct contact with the metal bond pad 24 for improved heat dissipation. There is no electrically isolation for the metallic material 51 filling the cut out 50 giving access to the metallic n-contact 45, since this cut out 50 is completely embedded in n-doped semiconductor material.

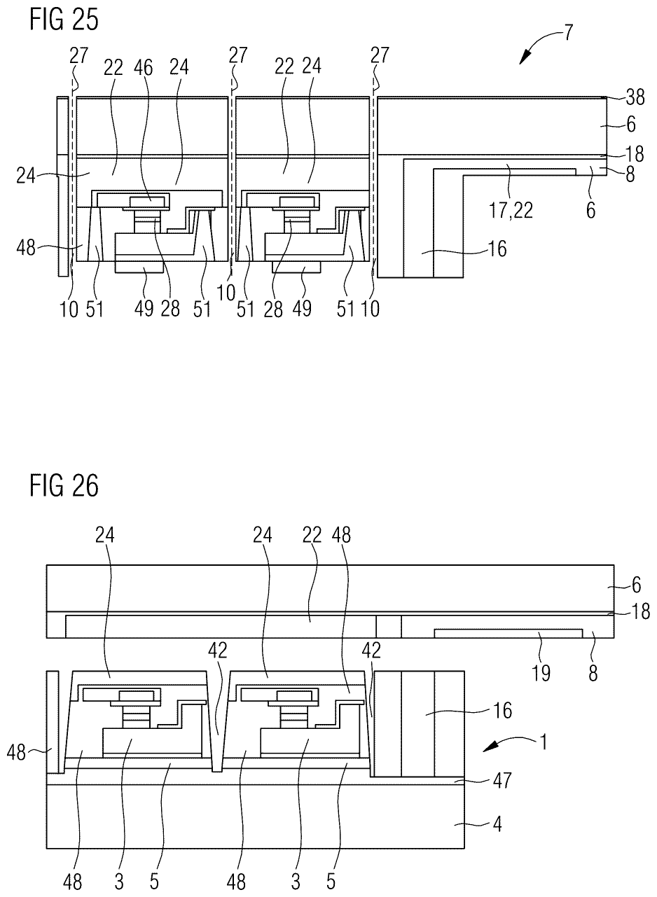

The wafer compound 7 is separated in single semiconductor chips (FIG. 25), for example by sawing through separation lines 27.

In the method of the exemplary embodiment of FIGS. 15 to 25, the electrical path 26 in the wafer compound 7 between the first ECE contact 8 and the sacrificial layer 5 for the current flow is electrically isolated from the other electrically conductive elements, particularly from the chip regions 3 comprising particularly the active zone 28, the metallic p-contact 44 and the metallic n-contact 45. The structures for electrical isolation of the electrical path 26 of the current flow are particularly placed on the carrier wafer 6 and the growth substrate 4 of the functional semiconductor wafer 1. Particularly, the metallic p-contact 44 and the metallic n-contact 45 are electrically isolated from the electrochemical etchant 12. The electrical connection for the current flow during electrochemical etching of the sacrificial layer 5 takes place over the further n-doped semiconductor layer 42 and the sacrificial layer 5. As a consequence, the carrier wafer 6 can be electrically conductive or electrically isolating.

In contrast to the method of the exemplary embodiment of FIGS. 15 to 25, during the method of the exemplary embodiment of FIGS. 26 to 28, recesses 52 are formed between the chip regions 3 of the functional semiconductor wafer 1 before bonding the functional semiconductor wafer 1 to the carrier wafer 6. For example, the recesses 52 are formed by dry chemical etching such as reactive ion etching (RIE). The recesses 52 penetrate the isolation material 48 between the chip regions 3 until the further n-doped semiconductor layer 47 on the growth substrate 4 (FIG. 26). The recesses 42 have inclined side faces with respect to a normal of the growth substrate 4.

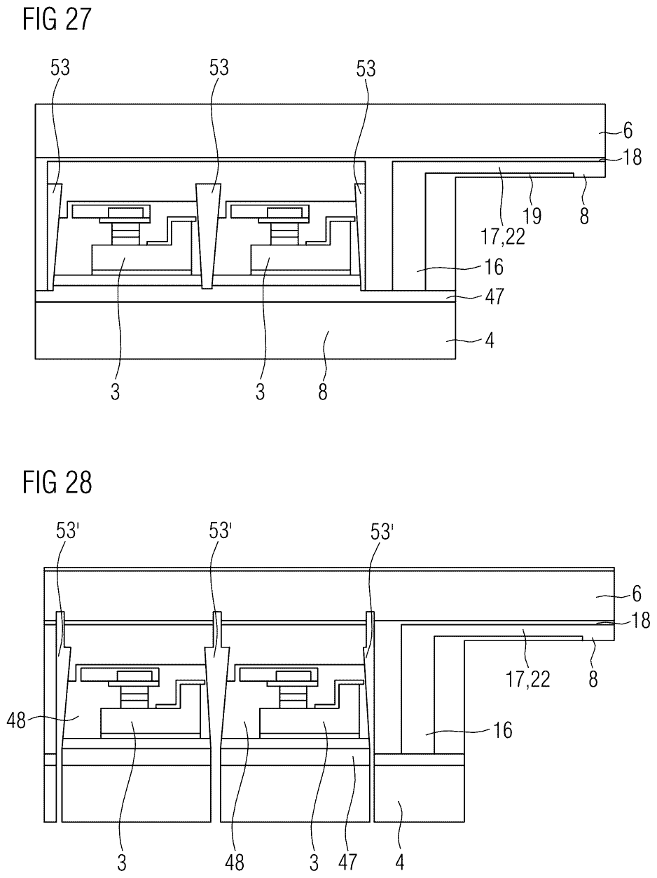

The functional semiconductor wafer 1 and the carrier wafer 6 are bonded together to form a wafer compound 7 (FIG. 27). After bonding, the recesses 52 form closed cavities 53 between the chip regions 3.

As shown in FIG. 28, the closed cavities 53 are opened by forming grooves 10 between the chip regions 3 through the growth substrate 4. The opened cavities 53′ have a larger volume than the grooves 10 formed in the method of the exemplary embodiment of FIG. 15 to 25. The opened cavities 53′ serve as reservoirs for the electrochemical etchant 12 during the electrochemical etching. The reservoirs formed by the opened cavities 53′ enables a better exchange of the electrochemical etchant 12 during electrochemical etching at a later stage. This enhances electrochemical etching.

The, the same steps are performed as already described in connection with FIGS. 19 to 25.

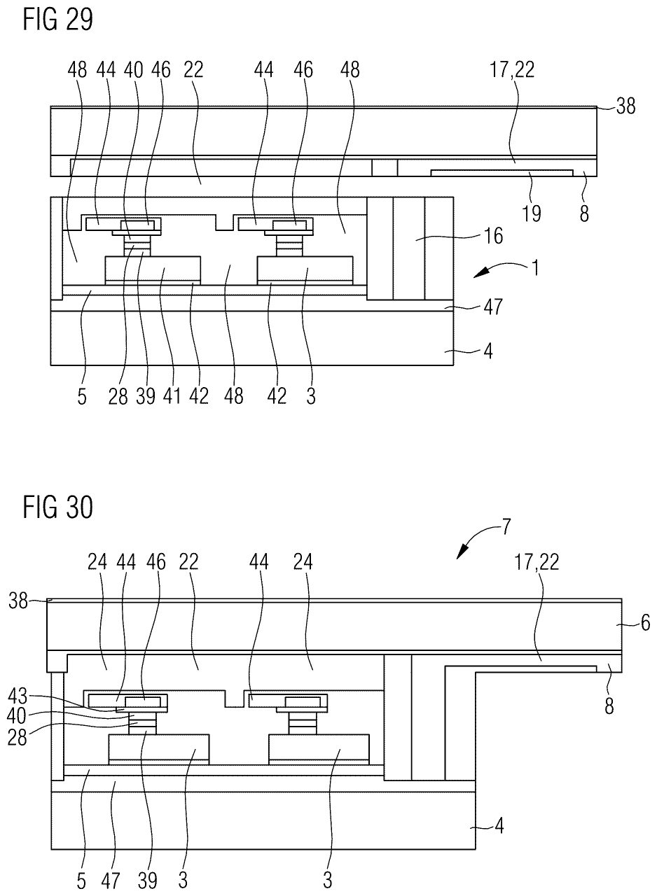

In contrast to the method according to the exemplary embodiment of FIGS. 15 to 25, the chip regions 3 of the functional semiconductor wafer 1 according to the method of the exemplary embodiment of FIGS. 29 to 31 do not comprise a metallic n-contact 45 (FIG. 29). As already described, the carrier wafer 6 and the functional semiconductor wafer 1 are bonded together.

After bonding, the chip regions 3 and particularly the p-doped semiconductor layer 40 and n-doped semiconductor layer 39 embedding the active zone 28 are completely electrically isolated from a later applied electrochemical etchant 12 (FIG. 30).

After bonding, grooves 10 are formed between the chip regions in the isolator material and the sacrificial layer 5 is removed by electrochemical etching. Then, the steps as already described in connection with FIGS. 19 to 22 are carried out. The p-contact 44 is electrically conductively connected as already described. In order to electrically conductively connect the n-contacts 45 of the chip regions 3, cut outs 50 are formed in the n-doped material of the chip regions 3 and filled with an electrically conductive material 51 such as a metal.

There is no electrical isolation for the n-contact 45 required in this exemplary embodiment of the method, since the cut outs 51 are formed completely in n-doped semiconductor material.

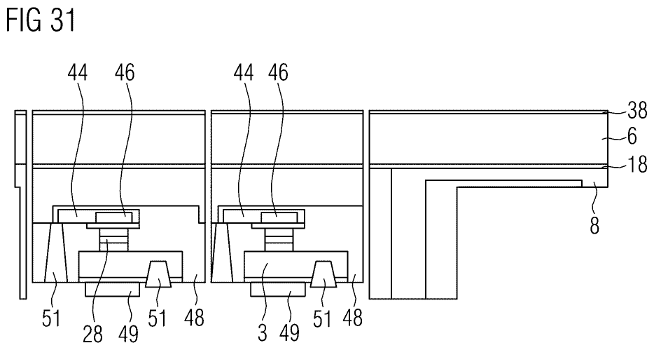

The wafer compound 7 is separated in single semiconductor chips (FIG. 31).

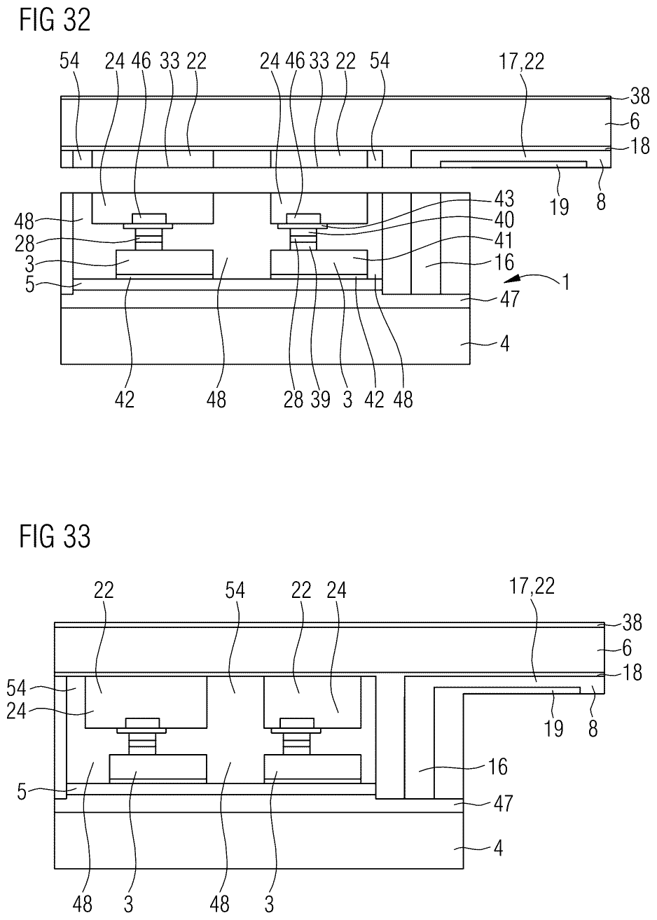

In contrast to the method according to the exemplary embodiment of FIGS. 15 to 25, the metallic mounting areas 33 over the carrier wafer 6 of the exemplary embodiment of FIGS. 32 to 35 are electrically isolated from each other by a further isolation material 54 (FIG. 32). Also, the metallic bond pads 24 are electrically isolated by an isolation material 48. As shown in FIG. 33, the carrier wafer 6 and the functional semiconductor wafer 1 are bonded together, particularly via the metallic bond pads 24 over the chip regions 3 of the functional semiconductor wafer 1 and the metallic mounting areas 33 electrically isolated from each other on the carrier wafer 6 (FIG. 33). After bonding the isolation material 48 electrically isolating the chip regions 3 and the further isolation material 54 electrically isolating the metallic mounting areas 33 are connected to each other.

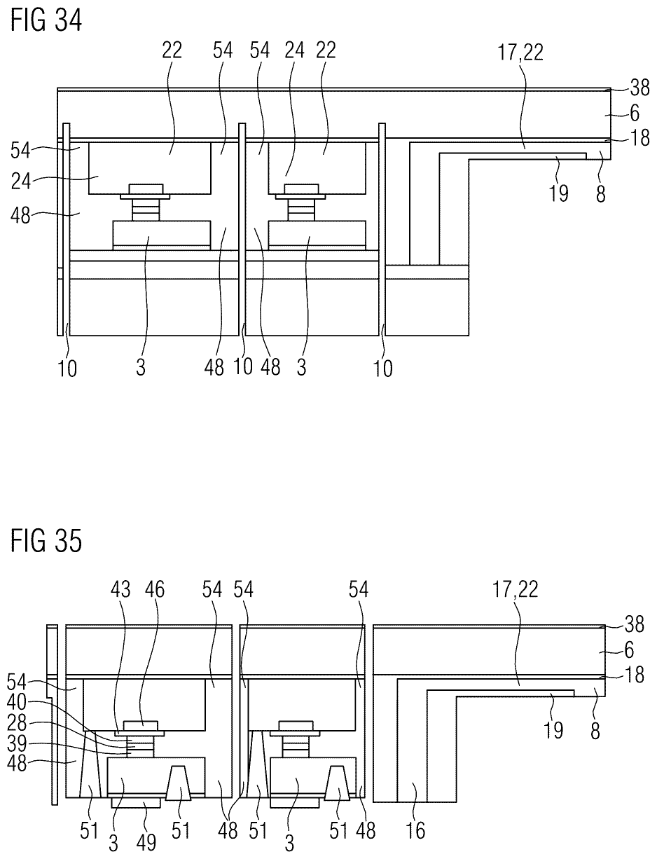

Grooves 10 are formed through the isolation material 48 and the further isolation material 54 (FIG. 34).

Then, further process steps are conducted as already described for example in connection with FIGS. 19 to 25 and 31 such that single semiconductor chips are achieved as for example shown in FIG. 35.

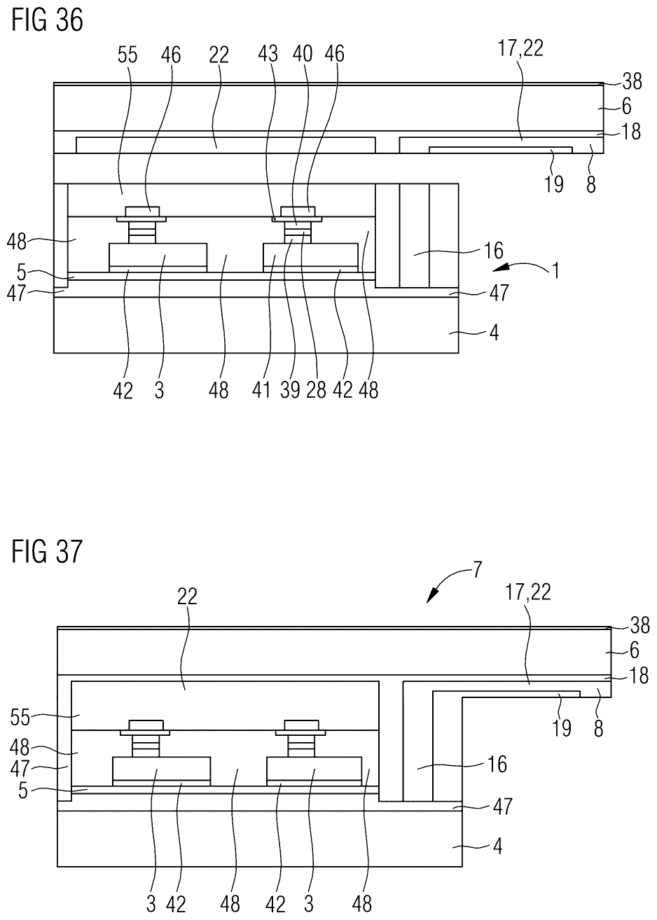

In contrast to the method of the exemplary embodiment of FIGS. 15 to 25, the functional semiconductor wafer 1 used during the method according to the embodiment of FIGS. 36 to 38 comprises a continuous p-contact layer 55 instead of electrically isolated p-contacts 44 (FIG. 36). The continuous p-contact layer 55 is a metallic layer at present.

The carrier wafer 6 and the functional semiconductor wafer 1 are bonded together via a metal layer 22 over a main surface of the carrier wafer 6 and the continuous p-contact layer 55 (FIG. 37).

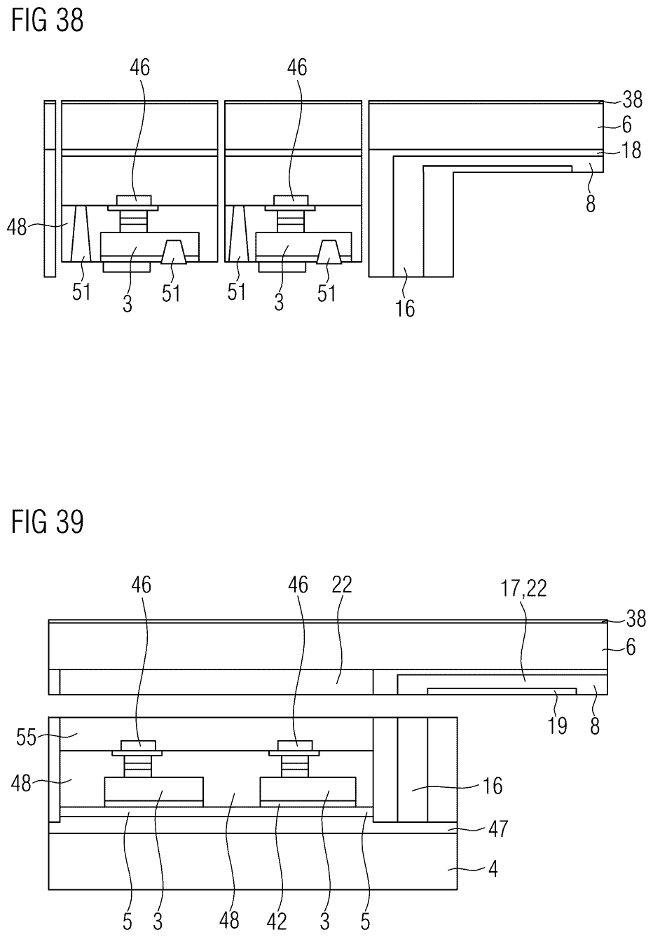

After bonding the same processes are conducted as already explained in connection with FIGS. 19 to 25 and 31 such that single semiconductor chips are achieved (FIG. 38). In this method, the continuous p-contact layer 55 is in contact with an electrochemical etchant 12 during electrochemical etching.

During the method according to the exemplary embodiment of FIG. 39, the metallic n-contact is electrically conductively connected after bonding and electrochemical etching, as already described in connection with FIGS. 29 to 31. Further, the functional semiconductor wafer 1 comprises a metal layer 22 in direct contact with an electrically conductively carrier wafer 6. Instead of electrically isolated p-contacts 44 there is provided a metallic continuous p-contact layer 55 as already described in connection with FIGS. 36 to 38. The metallic continuous p-contact layer 55 is connected to the metal layer 22 during bonding. Therefore, the generation of cut outs 50 for electrical conductively connection of the p-contacts 44 is not necessary, because electrical connection of the metallic p-contacts 44 of the finished semiconductor chips can take place over the carrier wafer 6.

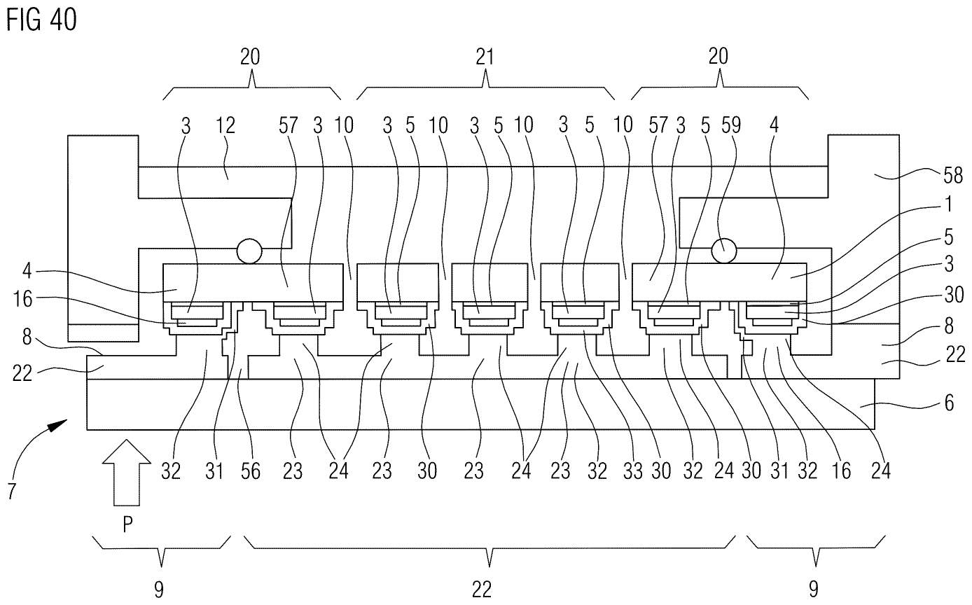

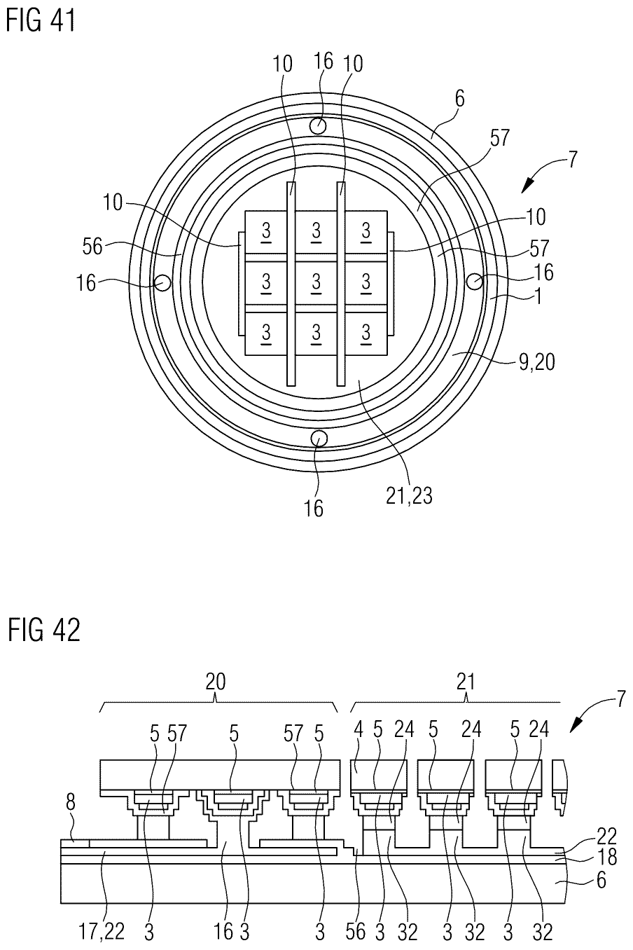

In the method of the exemplary embodiment of FIGS. 40 to 41 the wafer compound 7 is arranged in a horizontal direction DH in an electrochemical etchant 12 in contrast to the exemplary embodiments described above. The horizontal direction DH runs perpendicular to the vertical direction Dv.

In general, the design of the functional semiconductor wafer 1 and/or the carrier wafer 6 is embodied as already described in above connection with the other Figures.

The wafer compound 7 of FIG. 40 comprises an electrically insulating silicon wafer as carrier wafer 6 and a functional semiconductor wafer 1. The carrier wafer 6 comprises a metal layer 22 on a main surface, wherein the metal layer 22 has protrusions 32 with metallic mounting areas 33. The functional semiconductor wafer 1 comprises chips regions 3 covered by metallic bond pads 24. Between the chip regions 3 and the metallic bond pads 24, an insulating layer 30 is arranged for electrical isolation of the chip regions 3. The functional semiconductor wafer 1 and the carrier wafer 6 are bonded together via the metallic bond pads 24 and the metallic mounting areas 33 (FIG. 40).

In a central region 21 of the functional semiconductor wafer 1, the chip regions 3 are separated from each other by grooves 10 such that a sacrificial layer 5 between the chip regions 3 and a growth substrate 4 of the functional semiconductor wafer 1 is freely accessible for an electrochemical etchant 12.

A boundary region 20 of the functional semiconductor wafer 1 surrounding the central region 21 comprises at present a row of outermost chip regions 3. The row of outermost chip regions 3 in the boundary region 20 is part of a further electrical contact 16 electrically conductively connected to a first ECE contact 8 on the carrier wafer 6. The further electrical contact 16 comprises an electrically conductive layer 31 arranged over an insulating layer 30 covering the chip regions 3 and being in direct contact with the growth substrate 4 of the functional semiconductor wafer 1.

The further electrical contact 16 is electrically isolated from the chip regions 3 in the central region 21 of the functional semiconductor wafer 1 by a gap 56 in the metal layer 22 on the carrier wafer 6. Directly adjacent to the outermost row of chip regions 3, there is a further row of chip regions 3 forming a barrier 57 for the outermost chip regions 3 against the electrochemical etchant 12.

The wafer compound 7 is fixed in a wafer holder 58. The wafer holder 58 has a sealing rim 59 sealing the wafer compound 7 to the wafer holder 58. Further, the wafer holder 58 electrically conductively connects the first ECE contact 8 on the carrier wafer 6 externally.

As can be seen in FIG. 41 showing a plan view of the arrangement of FIG. 40, the outermost chip regions 3 form round further electrical contacts, while the adjacent chip regions 3 form a ring shaped barrier 57. Between the ring shaped barrier 57 and the outermost chip regions 3 forming the further electrical contact 16, the sealing rim 59 is arranged. Also, the sealing rim 59 is ring shaped.

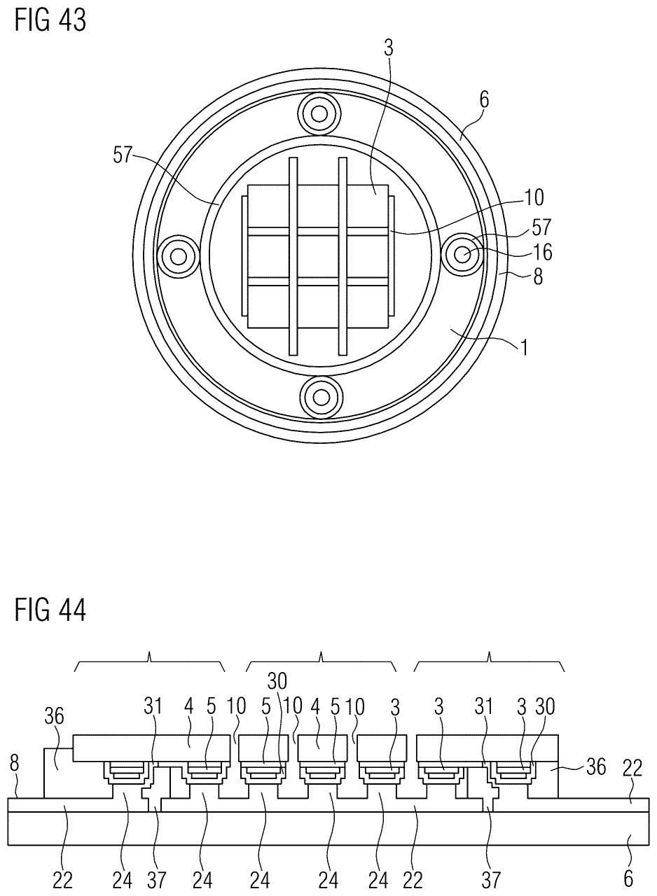

The wafer compound 7 according to the exemplary embodiment of FIGS. 42 and 43 is embodied as already described in connection with FIG. 8. Particularly, in a boundary region 20 of the functional semiconductor wafer 1, there are three rows of chip regions 3, wherein the chip regions 3 within the middle forms a further electrical contact 16 electrically conductively connected to the first ECE contact 8 by a conductor track 17 on the carrier wafer 6. Particularly, the further electrical contact 16 forms a feed-through for electrical current from the first ECE contact 8 to the growth substrate 4 and particularly to a sacrificial layer 5 arranged between the growth substrate 4 and chip regions 3 within a central region 21 of the functional semiconductor wafer 1 after bonding to a carrier wafer 6. The row of chip regions 3 in the middle is surrounded in a ring-shaped manner by further chip regions 3 forming a barrier 57 against an electrochemical etchant 12 (see particularly FIG. 43).

As for example shown in FIG. 44, it is also possible that the further electrical contact 16 on the functional semiconductor wafer 1 is embedded in a dielectric bonding material 36, as already explained in connection with FIG. 14.

In FIGS. 41 and 43 four further electrical contacts 16 on the functional semiconductor wafer 1 are exemplarily shown. The minimum number of further electrical contacts 16 is one. Moreover, the further electrical contact 16 can embodied in a ring-shaped manner around the wafer compound 7.

The invention is not limited to the description of the exemplary embodiments. Rather, the invention comprises each new feature as well as each combination of features, particularly each combination of features of the claims, even if the feature or the combination of features itself is not explicitly given in the claims or the exemplary embodiments.

1-18. (canceled)

19. A method for manufacturing a plurality of semiconductor chips, the method comprising:
providing a functional semiconductor wafer comprising an epitaxial semiconductor layer sequence with a plurality of chip regions, wherein the epitaxial semiconductor layer sequence is arranged on a growth substrate and a sacrificial layer is arranged at least between the chip regions and the growth substrate;
providing a carrier wafer;
bonding the functional semiconductor wafer and the carrier wafer together such that a wafer compound is achieved;
generating grooves between the chip regions through the growth substrate and the sacrificial layer such that the sacrificial layer is accessible through the grooves;
arranging the wafer compound and a ECE contact in an electrochemical etchant; and
electrochemical etching the sacrificial layer by applying an ECE voltage between a first ECE contact and the second ECE contact.

20. The method according to claim 19, wherein the chip regions are electrically isolated against the ECE voltage.

21. The method according to claim 19, wherein the carrier wafer has a larger diameter than the functional semiconductor wafer.

22. The method according to claim 19,
wherein at least one further electrical contact of the functional semiconductor wafer is electrically conductively connected to the first ECE contact on the carrier wafer during bonding, and
wherein the further electrical contact comprises a chip region covered at least partially with an electrically conductive layer.

23. The method according to claim 22, wherein the further electrical contact is laterally completely embedded in a dielectric bonding material.

24. The method according to claim 22, further comprising arranging a dielectric layer between the main face of the carrier wafer and metallic mounting areas.

25. The method according to claim 19,
wherein bonding the functional semiconductor wafer to the carrier wafer comprises connecting metallic bond pads over the chip regions to metallic mounting areas on the carrier wafer, and
wherein the chip regions are electrically isolated from the metallic bond pads by an insulating layer.

26. The method according to claim 25, wherein the metallic mounting areas of the carrier wafer are part of a metal layer over a main face of the carrier wafer.

27. The method according to claim 19,
wherein at least two grooves completely penetrate the functional semiconductor wafer in a lateral direction such that at least two completely separated parts of the functional semiconductor wafer are generated,
wherein each part of the functional semiconductor wafer comprises a further electrical contact electrically conductively connected to the first ECE contact on the carrier wafer.

28. The method according to claim 19,
wherein the chip regions comprises a n-contact and a p-contact, and
wherein at least one of the n-contact and the p-contact is electrically isolated against the ECE voltage.

29. The method according to claim 19,
wherein the chip regions comprises a n-contact and a p-contact, and
wherein at least one of the n-contact and the p-contact is not in direct contact with the electrochemical etchant during the electrochemical etching.

30. The method according to claim 19,
wherein at least two functional semiconductor wafers are bonded to the carrier wafer, and
wherein each functional semiconductor wafer comprises at least one further electrical contact electrically conductively connected to the first ECE contact on the carrier wafer during bonding.

31. The method according to claim 19, wherein the sacrificial layer comprises a highly n-doped semiconductor material.

32. The method according to claim 19, wherein the growth substrate comprises GaN or sapphire.

33. The method according to claim 19, wherein the wafer compound is arranged in a vertical direction in the electrochemical etchant.

34. The method according to claim 19, wherein the wafer compound is arranged in a horizontal direction in the electrochemical etchant.

35. The method according to claim 34, wherein the functional semiconductor wafer comprises at least one further electrical contact formed as a ring surrounding the chip regions and electrically conductively connected to the first ECE contact on the carrier wafer.

36. The method according to claim 34, wherein the functional semiconductor wafer comprises a ring shaped barrier arranged between the chip regions and the further electrical contact.
